(19) United States
(12) Patent Application Publication
(10) Pub. No.: US 2021/0384408 A1
(43) Pub. Date: Dec. 9, 2021

(54) DIELECTRIC ELASTOMER TRANSDUCER

(71) Applicants: Seiki CHIBA, Meguro-ku, Tokyo (JP); Mikio WAKI, Sakura-shi, Tochigi (JP); ZEON CORPORATION, Chiyoda-ku, Tokyo (JP)

(72) Inventors: Seiki CHIBA, Meguro-ku, Tokyo (JP); Mikio WAKI, Sakura-shi, Tochigi (JP); Mitsugu UEJIMA, Chiyoda-ku, Tokyo (JP); Makoto TAKESHITA, Chiyoda-ku, Tokyo (JP)

(73) Assignees: Seiki CHIBA, Meguro-ku, Tokyo (JP); Mikio WAKI, Sakura-shi, Tochigi (JP); ZEON CORPORATION, Chiyoda-ku, Tokyo (JP)

(21) Appl. No.: 17/286,890

(22) PCT Filed: Oct. 23, 2019
(86) PCT No.: PCT/JP2019/041432

§ 371 Date: Apr. 20, 2021

(30) Foreign Application Priority Data
Oct. 31, 2018 (JP) 2018-204560

(51) Int. Cl. H01L 41/047; H01L 41/193; H01L 41/083; H01L 41/297

(52) U.S. Cl. CPC H01L 41/047; H01L 41/297; H01L 41/083; H01L 41/193

(57) ABSTRACT

A dielectric elastomer transducer A1 includes a plurality of dielectric elastomer elements each including a dielectric elastomer layer 11 and a pair of electrode layers 12 and 13 flanking the dielectric elastomer layer 11. The plurality of dielectric elastomer elements include adjacent dielectric elastomer elements 1. One electrode layer 12 of one of the adjacent dielectric elastomer elements and one electrode layer 12 of the other one of the adjacent dielectric elastomer element have the same potential. Such a configuration ensures more stable use of the dielectric elastomer elements.

### TECHNICAL FIELD

The present invention relates to a dielectric elastomer transducer.

### BACKGROUND ART

As transducers with excellent energy conversion efficiency, dielectric elastomer transducers having dielectric elastomer layers are attracting attention. Such a dielectric elastomer transducer converts one form of energy into another by using deformation (expansion and contraction) of the dielectric elastomer layer.

For example, the dielectric elastomer layer to be deformed by applying an external force may be used to generate electric power by converting mechanical energy into electrical energy. In this case, the dielectric elastomer transducer acts as a power generator. In another example, the dielectric elastomer layer to be deformed by electric charges induced on a pair of electrodes may be used to generate a driving force. In this case, the dielectric elastomer transducer acts as an actuator. In yet another example, the dielectric elastomer transducer can be used as a sensor element by utilizing changes in the capacitance of the dielectric elastomer transducer as a capacitor.

For example, when the dielectric elastomer transducer is used as an actuator, it may be configured as a combination of a plurality of dielectric elastomer elements that each have a dielectric elastomer layer and a pair of electrode layers. Such a configuration allows for strengthening the driving force and extending the stroke. In this case, however, a significantly high voltage (potential difference) is applied to the pairs of electrodes of the dielectric elastomer elements. This may lead to an unintended electric behavior occurring between the electrode layers of adjacent dielectric elastomer elements.

### PRIOR ART DOCUMENT

### Patent Document

Patent Document 1: JP-A-2009-124875

### SUMMARY OF THE INVENTION

### Technical Problem

The present invention has been conceived in view of the circumstances noted above and aims to provide a dielectric elastomer transducer that allows more stable use of a plurality of dielectric elastomer elements.

### Solution to Problem

In accordance with the present invention, there is provided a dielectric elastomer transducer comprising: a plurality of dielectric elastomer elements each including a dielectric elastomer layer and a pair of electrode layers flanking the dielectric elastomer layer. The plurality of dielectric elastomer elements include a first dielectric elastomer element and a second dielectric elastomer element that are adjacent to each other, and one of the electrode layers of the first dielectric elastomer element and one of the electrode layers of the second dielectric elastomer element are configured to have a same potential.

According to a preferred embodiment of the present invention, each of the dielectric elastomer layers has an annular shape having an inner peripheral edge and an outer peripheral edge, where the inner peripheral edges or the outer peripheral edges of adjacent dielectric elastomer elements are fixed to each other, and the plurality of dielectric elastomer elements as a whole are elongated in an axial direction, with the respective dielectric elastomer elements having a shape of tubular frustum. The electrode layers of each dielectric elastomer element include an outer electrode layer in a radial direction, where the outer electrode layer has zero or ground potential.

According to a preferred embodiment of the present invention, each of the dielectric elastomer layers has an annular shape having an inner peripheral edge and an outer peripheral edge. The plurality of dielectric elastomer elements are stacked on each other with adjacent inner peripheral edges being fixed to each other and with adjacent outer peripheral edges being fixed to each other.

According to a preferred embodiment of the present invention, dielectric elastomer transducer, comprising at least one dielectric elastomer element made up of a dielectric elastomer layer and an electrode layer, wherein the dielectric elastomer element comprises: a pair of dielectric elastomer layers stacked on each other; an inner electrode layer flanked by the pair of dielectric elastomer layers; and a pair of outer electrode layers flanking the pair of dielectric elastomer layers and having a same potential.

According to a preferred embodiment of the present invention, each of the outer electrode layers has zero or ground potential.

According to a preferred embodiment of the present invention, the dielectric elastomer element is wound in a roll shape, and the outer electrode layers have respective parts facing each other.

According to a preferred embodiment of the present invention, the at least one dielectric elastomer element comprises a plurality of dielectric elastomer elements that are stacked on each other, and the outer electrode layers of adjacent dielectric elastomer elements have a same potential.

### Advantages of Invention

According to the present invention, a plurality of dielectric elastomer elements can be used more stably.

Other features and advantages of the present invention will be more apparent from detailed description given below with reference to the accompanying drawings.

### BRIEF DESCRIPTION OF THE DRAWINGS

FIG. 1 is a perspective view showing a dielectric elastomer transducer according to a first embodiment of the present invention.

FIG. 2 is a cross-sectional view along line II-II in FIG. 1.

FIG. 3 is a plan view showing a dielectric elastomer transducer according to a second embodiment of the present invention.

FIG. 4 is a cross-sectional view along line IV-IV in FIG. 3.

FIG. 5 is a plan view showing a dielectric elastomer transducer according to a third embodiment of the present invention.

FIG. 6 is a cross-sectional view along line VI-VI in FIG. 5, with an inset showing an enlarged cross-section.

FIG. 7 is a cross-sectional view showing a dielectric elastomer transducer according to a fourth embodiment of the present invention.

FIG. 8 is a cross-sectional view showing a variation of the dielectric elastomer transducer according to the first embodiment of the present invention.

### MODE FOR CARRYING OUT THE INVENTION

Preferred embodiments of the present invention are described below with reference to the accompanying drawings.

### First Embodiment

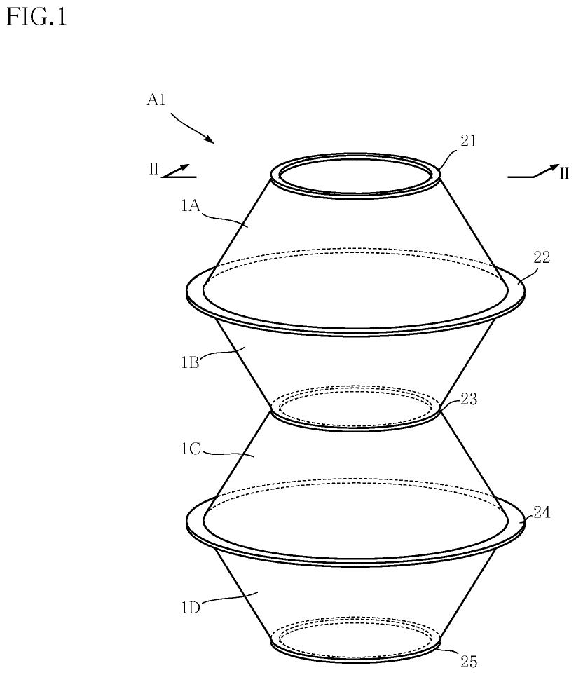

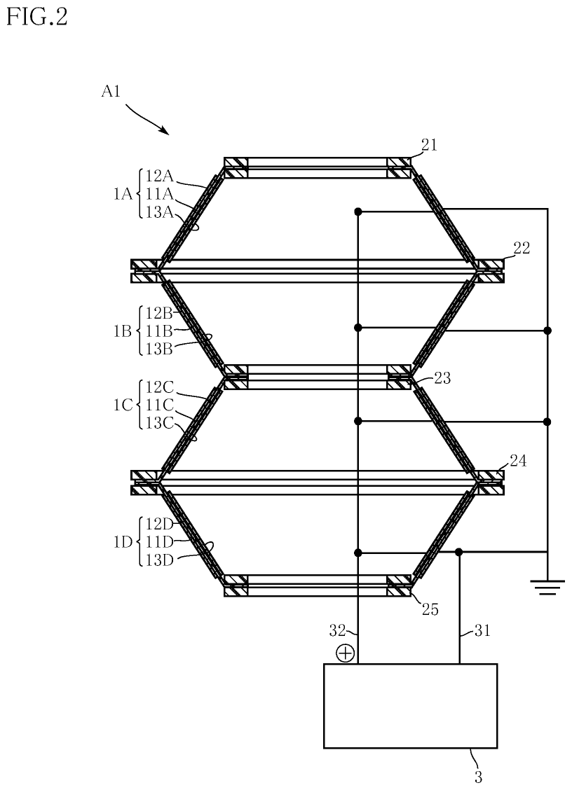

FIGS. 1 and 2 show a dielectric elastomer transducer according to a first embodiment of the present invention. A dielectric elastomer transducer A1 according to the present embodiment includes a plurality of dielectric elastomer elements 1, a plurality of supporting members 21, 22, 23, 24, and 25, and a controller 3. The application of the dielectric elastomer transducer A1 is not particularly limited. In the following description, the dielectric elastomer transducer A1 is used as an actuator as an example.

The dielectric elastomer elements 1 have the same configuration and each have a dielectric elastomer layer 11 and a pair of electrode layers 12 and 13. In FIGS. 1 and 2, the plurality of dielectric elastomer elements 1 are distinguished by separate reference signs, i.e., dielectric elastomer elements LA, 1B, 1C, and 1D. In FIG. 2, the components of the dielectric elastomer elements 1A to 1D are also distinguished and indicated by dielectric elastomer layers 11A to 11D, electrode layers 12A to 12D, and electrode layers 13A to 13D. Note that the number of dielectric elastomer elements 1 is not particularly limited, and may be no greater than three or no less than five.

The dielectric elastomer layer 11 contains one or more elastomers (polymers having rubbery elasticity). The elastomers are not limited to any specific types and may be thermoset elastomers or thermoplastic elastomers, for example.

The thermoset elastomers are not limited to any specific types and may be natural rubbers, synthetic rubbers, silicone rubber elastomers, urethane rubber elastomers and fluorocarbon rubber elastomers, for example.

Each of the thermoplastic elastomers may be a copolymer of an aromatic vinyl-based monomer and a conjugated diene-based monomer. Specifically, the copolymer of an aromatic vinyl-based monomer and a conjugated diene-based monomer may be: diblock copolymers such as a styrene-butadiene block copolymer or a styrene-isoprene block copolymer; triblock copolymers such as a styrene-butadiene-styrene block copolymer, a styrene-isoprene-styrene block copolymer (SIS), a styrene-butadiene-isoprene block copolymer or a styrene-isobutylene-styrene block copolymer (SIBS); multiblock styrene-containing block copolymers such as a styrene-butadiene-styrene-butadiene block copolymer, a styrene-isoprene-styrene-isoprene block copolymer, a styrene-butadiene-isoprene-styrene block copolymer, a styrene-butadiene-styrene-isoprene block copolymer, or a styrene-isobutylene-butadiene-styrene, or a hydrogenated or partially hydrogenated product of these. Among these copolymers, a block copolymer such as SIS is more preferably used.

Note that the dielectric elastomer layer 11 may include one or more other materials in addition to the elastomers noted above. Examples of such other materials include various additives.

In the present embodiment, the dielectric elastomer layer 11 has an annular shape with a circular inner peripheral end and a circular outer peripheral end, when no external force is applied. The dielectric elastomer layer 11 has a frustum tubular shape when the dielectric elastomer layer 11 is elongated in an axial direction that coincides with the vertical direction in the figure, with the inner peripheral end or the outer peripheral end being fixed to the inner peripheral end or the outer peripheral end of an adjacent dielectric elastomer layer 11. It is possible to employ a weight, a support structure, or an elastic member (not shown) as appropriate in order to maintain the frustum tubular shape of the dielectric elastomer layer 11.

The electrode layers 12 and 13 are provided on the respective sides of the dielectric elastomer layer 11 to sandwich the dielectric elastomer layer 11. In the present embodiment, each of the electrode layers 12 and 13 may have an annular shape when an external force is not applied so as to correspond to the shape of the dielectric elastomer layer 11.

The electrode layers 12 and 13 may be made of any of various conductive materials sufficiently deformable following the deformation of the dielectric elastomer layer 11. The material of the electrode layers 12 and 13 contains one or more conductive materials, including carbon materials, conductive polymer compounds, and metallic materials. Examples of carbon materials include graphite, fullerene, carbon nanotubes (CNTs), and graphene. The carbon materials may be subjected to one or more processes, including metal doping, metal-encapsulation, and metal plating. Examples of the conductive polymer compounds include polyacethylene, polythiophene, polypyrrole, polyphenylene, polyphenylene vinylene, and polybenzothiazole. Examples of the metallic materials include silver (Ag), gold (Au), and aluminum (Al), as well as alloys of such metals.

In the present embodiment, the electrode layers 12A to 12D are provided on the outer surfaces of the dielectric elastomer layers 11A to 11D that each have a frustum tubular shape, and the electrode layers 13A to 13D are provided on the inner surfaces of the dielectric elastomer layers 11A to 11D. Accordingly, in the adjacent dielectric elastomer elements 1A and 1B, the electrode layers 13A and 13B are arranged between the dielectric elastomer layer 11A and the dielectric elastomer layer 11B. In the adjacent dielectric elastomer elements 1B and 1C, the electrode layers 12B and 12C are arranged between the dielectric elastomer layer 11B and the dielectric elastomer layer 11C. In the adjacent dielectric elastomer elements 1C and 1D, the electrode layers 13C and 13D are arranged between the dielectric elastomer layer 11C and the dielectric elastomer layer 11D.

The supporting members 21, 22, 23, 24, and 25 are examples of supporting means for supporting the plurality of dielectric elastomer elements 1 in a state where the plurality of dielectric elastomer elements 1, each forming a frustum tubular shape, are connected to each other. The supporting means for supporting the plurality of dielectric elastomer elements 1 are not limited to having any particular configuration. In the illustrated example, the supporting members 21, 22, 23, 24, and 25 may be ring-like members made of an insulating resin. The supporting member 21 supports the inner peripheral end of the dielectric elastomer element 1A. The supporting member 22 supports the outer peripheral ends of the dielectric elastomer elements 1A and 1B. The supporting member 23 supports the inner peripheral ends of the dielectric elastomer elements 1B and 1C. The supporting member 24 supports the outer peripheral ends of the dielectric elastomer elements 1C and 1D. The supporting member 25 supports the inner peripheral end of the dielectric elastomer element 1D. In order to generate tension in the dielectric elastomer elements 1A, 1B, 1C, and 1D, the supporting member 21 may be fixed and the supporting member 25 may be provided with a weight (not shown). The weight causes the dielectric elastomer elements 1A, 1B, 1C, and 1D to stretch to generate tension.

The controller 3 realizes a process using the dielectric elastomer transducer A1. When the dielectric elastomer transducer A1 is used as an actuator, the controller 3 includes a power circuit that applies a voltage (a potential difference) to the electrode layers 12 and 13. When the dielectric elastomer transducer A1 is used to generate power, the controller 3 includes a power circuit that applies an initial voltage (an initial potential difference) and a recovery circuit that recovers electrical energy. When the dielectric elastomer transducer A1 is used as a sensor element, the controller 3 includes a detection circuit that detects a change in the capacitance of the dielectric elastomer transducer A1. In this example, description is provided assuming that the dielectric elastomer transducer A1 is used as an actuator and the controller 3 includes a power circuit.

The controller 3 and the dielectric elastomer elements 1A to 1D are connected via wires 31 and 32. The wire 31 is connected to the electrode layers 12A to 12D. The wire 32 is connected to the electrode layers 13A to 13D. In the illustrated example, the wire 31 is grounded. As such, the electrode layers 12A to 12D have zero or ground potential. The wire 32 applies a positive or negative voltage potential to the wire 31. In the illustrated example, the wire 32 is configured to apply a positive voltage. Accordingly, the electrode layers 13A to 13D have a positive potential. The application of voltage (potential) by the wire 32 to the electrode layers 13A to 13D is controlled by the controller 3 appropriately according to a desired degree of expansion and contraction of the dielectric elastomer transducer A1.

Next, advantages of the dielectric elastomer transducer A1 will be described.

In the dielectric elastomer elements 1A to 1D according to the present embodiment, the electrode layers 12 or the electrode layers 13 between adjacent dielectric elastomer layers 11 have the same potential. Accordingly, even if adjacent electrode layers 12 or 13 come close to or in contact with each other during, for example, the operation of the dielectric elastomer transducer A1, there is no risk of unintentional electrical shorting or discharge. Thus, the dielectric elastomer transducer A1 enables more stable use of the plurality of dielectric elastomer elements

In the dielectric elastomer transducer A1, the plurality of dielectric elastomer elements 1 (the dielectric elastomer layers 11), each forming a frustum tubular shape, are connected in the axial direction. The electrode layers 12A to 12D, which are provided on the outer surfaces of the plurality of dielectric elastomer elements 1 having the configuration as described above, are connected to the wire 31. As a result, the electrode layers 12A to 12D have zero or ground potential. Accordingly, even if an external conductor or the like comes close to or in contact with the electrode layers 12A to 12D during, for example, the operation of the dielectric elastomer transducer A1, there is no risk of unintentional electrical shorting or discharge. It is thus preferable for more stable use of the plurality of dielectric elastomer elements 1 in the dielectric elastomer transducer A1.

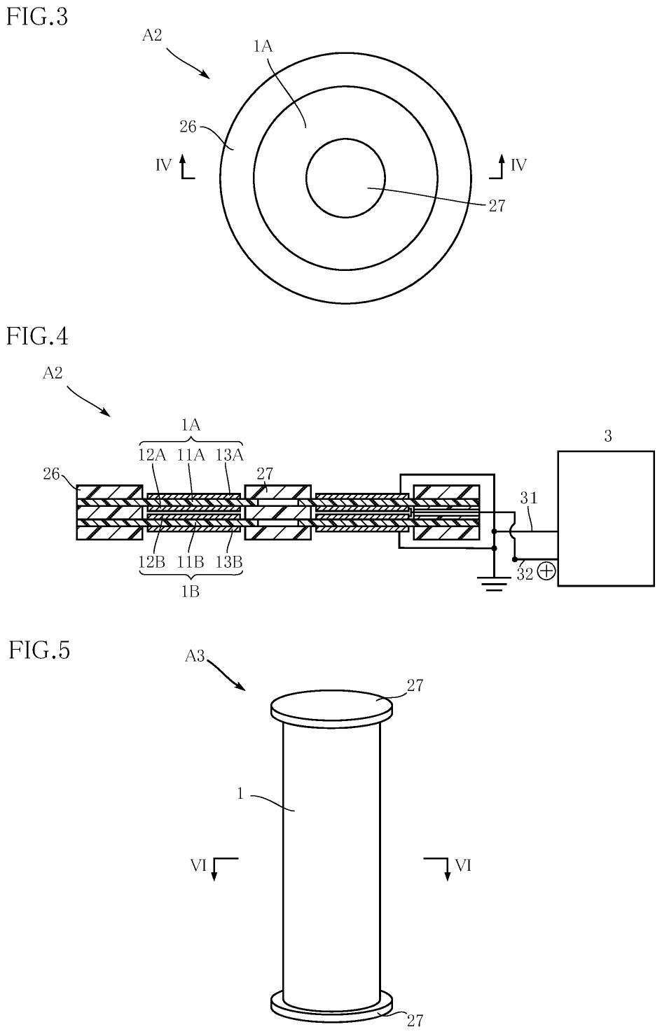

FIGS. 3 to 7 show other embodiments of the present invention. Note that in these figures, elements that are the same as or similar to the above embodiment are provided with the same reference signs as the above embodiment.

### Second Embodiment

FIGS. 3 and 4 show a dielectric elastomer transducer according to a second embodiment of the present invention. A dielectric elastomer transducer A2 according to the present embodiment includes a plurality of dielectric elastomer elements 1A and 1B.

Each of the dielectric elastomer elements 1A and 1B (dielectric elastomer layers 11A and 11B) has an annular shape in the illustrated example, but is not limited to any particular shape. The dielectric elastomer elements 1A and 1B are stacked on each other.

The outer peripheral ends of the dielectric elastomer layers 11A and 11B are fixed to each other via a supporting member 26. The supporting member 26 is composed of a plurality of ring-like members made of an insulating material, for example. The inner peripheral ends of the dielectric elastomer layers 11A and 11B are fixed to each other via a supporting member 27. The supporting member 27 is composed of a plurality of disc-like members made of an insulating material, for example.

In the adjacent dielectric elastomer elements 1A and 1B according to the present embodiment, the electrode layers 12A and 12B are arranged between the dielectric elastomer layer 11A and the dielectric elastomer layer 11B. The electrode layers 13A and 13B are arranged on the outer surfaces of the dielectric elastomer layers 11A and 11B, respectively.

The electrode layers 13A and 13B are connected to the wire 31. The wire 31 is grounded. As such, the electrode layers 13A and 13B have zero or ground potential. The electrode layers 12A and 12B are connected to the wire 32. Accordingly, the electrode layers 12A and 12B have a positive potential, for example.

In the present embodiment, the electrode layers 12A and 12B between the dielectric elastomer layers 11A and 11B of the adjacent dielectric elastomer elements 1A and 1B also have the same potential. Accordingly, even if the electrode layers 12A and 12B come close to or in contact with each other during, for example, the operation of the dielectric elastomer transducer A2, there is no risk of unintentional electrical shorting or discharge. Thus, the dielectric elastomer transducer A2 enables more stable use of the plurality of dielectric elastomer elements 1.

Furthermore, the electrode layers 13A and 13B provided on the outer sides have zero or ground potential. Accordingly, even if an external conductor or the like comes close to or in contact with the electrode layers 13A and 13B, there is no risk of unintentional electrical shorting or discharge. It is thus preferable for more stable use of the plurality of dielectric elastomer elements 1 in the dielectric elastomer transducer A2.

### Third Embodiment

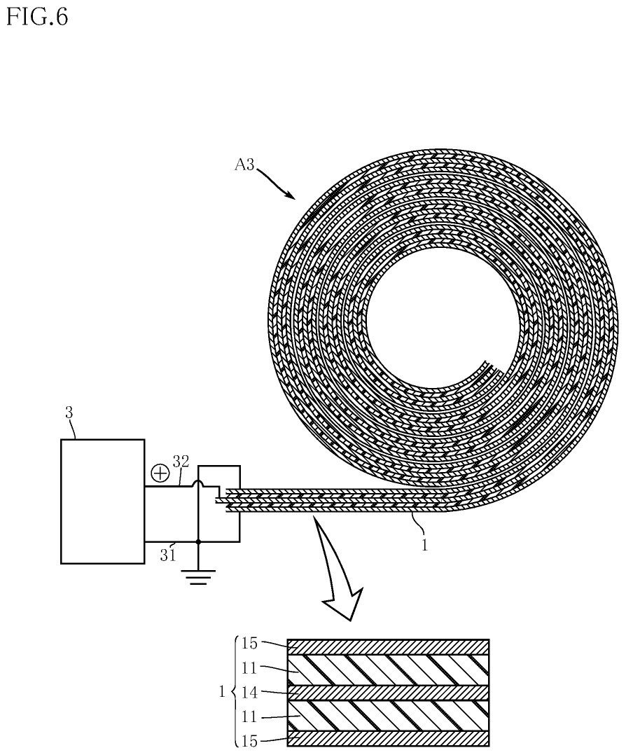

FIGS. 5 and 6 show a dielectric elastomer transducer according to a third embodiment of the present invention. A dielectric elastomer transducer A3 according to the present embodiment is different from that in the above embodiments in the configuration of the dielectric elastomer elements 1.

As shown by the partially enlarged cross-sectional view in FIG. 6, the dielectric elastomer element 1 according to the present embodiment has a pair of dielectric elastomer layers 11, an inner electrode layer 14, and a pair of outer electrode layers 15. The pair of dielectric elastomer layers 11 face each other. The inner electrode layer 14 is flanked by and fixed to the pair of dielectric elastomer layers 11. Each of the pair of outer electrode layers 15 is provided on the outer side of one of the pair of dielectric elastomer layers 11 and fixed to the dielectric elastomer layer 11.

In the present embodiment, the dielectric elastomer element 1 has an elongated shape and is wound in a cylindrical shape, for example. FIG. 5 shows the appearance of the cylindrically-wound dielectric elastomer element 1. The cross-sectional view of FIG. 6 shows a part of the cylindrically-wound dielectric elastomer element 1 in such a manner that the part is extended flatly for convenience of understanding. Parts of the cylindrically-wound dielectric elastomer element 1 are stacked on each other in the radial direction. In the stacked parts of the dielectric elastomer element 1, the outer electrode layers 15 come close to or in contact with each other.

Both ends of the cylindrically-wound dielectric elastomer element 1 in the axial direction are supported by the pair of supporting members 27, for example. When the dielectric elastomer transducer A3 is operated as an actuator, an elastic member may be provided between the pair of supporting members 27. The elastic member may apply an elastic force from within the dielectric elastomer element 1 to separate the pair of supporting members 27.

In the present embodiment, the pair of outer electrode layers 15 are connected to the controller 3 by a wire 31. The inner electrode layer 14 is connected to the controller 3 by a wire 32. The wire 31 is connected to the ground so that the pair of outer electrode layers 15 have zero or ground potential. The inner electrode layer 14 has a positive voltage, for example.

According to the present embodiment, the dielectric elastomer element 1 is wound in a cylindrical shape. In this way, in the parts of the dielectric elastomer element 1 that are stacked on each other, the outer electrode layers 15 come close to or in contact with each other. Since the pair of outer electrode layers 15 have the same potential, there is no risk of unintentional electrical shorting or discharge. Accordingly, the dielectric elastomer transducer A3 allows more stable use of the dielectric elastomer element 1 in which parts thereof are stacked on each other.

Furthermore, the outer electrode layers 15 provided on the outer sides of the dielectric elastomer transducer A3 have zero or ground potential. Accordingly, even if an external conductor or the like comes close to or in contact with the outer electrode layers 15, there is no risk of unintentional electrical shorting or discharge. It is thus preferable for more stable use of dielectric elastomer elements 1 in the dielectric elastomer transducer A3.

### Fourth Embodiment

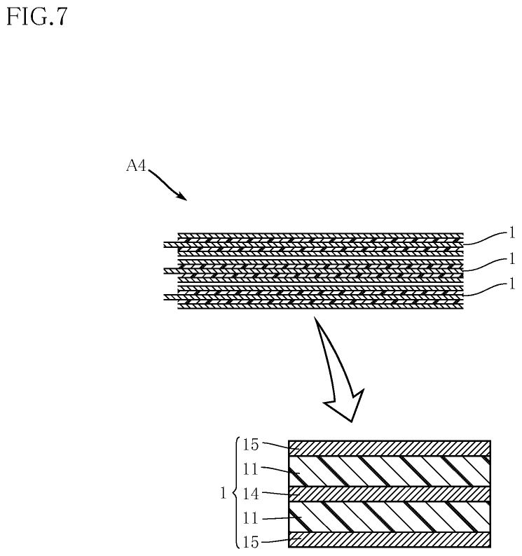

FIG. 7 shows a dielectric elastomer transducer according to a fourth embodiment of the present invention. A dielectric elastomer transducer A4 according to the present embodiment includes a plurality of dielectric elastomer elements 1. Each of the dielectric elastomer elements 1 has the same configuration as the dielectric elastomer transducer A3, and includes a pair of dielectric elastomer layers 11, an inner electrode layer 14, and a pair of outer electrode layers 15.

In the present embodiment, the plurality of dielectric elastomer elements 1 are stacked on each other. Specifically, such a configuration may be similar to a configuration that of the dielectric elastomer transducer A2. In the present embodiment, the pair of outer electrode layers 15 also have the same potential, preferably zero or ground potential.

Such an embodiment also allows more stable use of the plurality of dielectric elastomer elements 1.

### Variation of First Embodiment

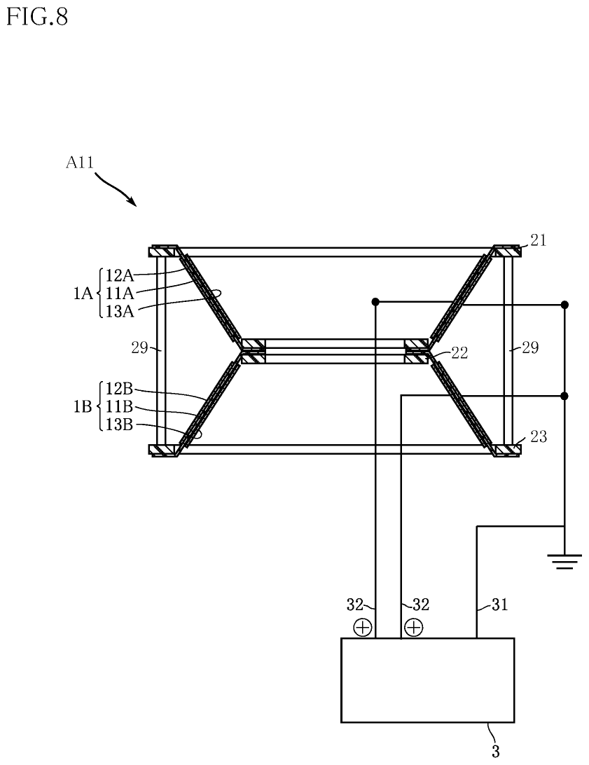

FIG. 8 shows a variation of the dielectric elastomer transducer A1. A dielectric elastomer transducer A11 of the present variation includes two dielectric elastomer elements 1A and 1B, and supporting members 21, 22, 23, and 29.

In the present variation, the two dielectric elastomer elements 1A and 1B are supported by the supporting members 21 and 23 that each have a relatively large diameter, and the supporting member 22 that has a relatively small diameter and is provided between the supporting members 21 and 23. The supporting member 29 is a rod-like member, for example, and fixes the supporting member 21 and the supporting member 23 in a state where the supporting members 21 and 23 are separated apart from each other in the vertical direction in the figure. When each of the supporting members 21 and 23 has an annular shape, for example, a plurality of supporting members 29 may be arranged at equal intervals (e.g., at a pitch of 90 degrees). With such a supporting configuration, the dielectric elastomer elements 1A and 1B together form a three-dimensional hourglass shape, where each of the two dielectric elastomer elements 1A and 1B has a frustum tubular shape elongated in an axial direction that coincides with the vertical direction in the figure in an initial state in which no voltage is applied. The dielectric elastomer elements 1A and 1B as described above are under tension.

Again in the present variation, the electrode layers 12A and 12B are provided on the outer sides of the dielectric elastomer layers 11A and 11B, the electrode layers 13A and 13B are provided on the inner sides of the dielectric elastomer layers 11A and 11B. The electrode layers l2A and 12B on the outer sides have zero or ground potential.

In the present variation, two wires 32 are provided and connected to the controller 3. One of the wires 32 is connected to the controller 3 and the electrode layer 12A of the dielectric elastomer element 1A. The other wire 32 is connected to the controller 3 and the electrode layer 12B of the dielectric elastomer element 1B. Such a configuration allows the controller to individually apply voltage to the dielectric elastomer elements 1A and 1B. For example, when a voltage is applied only to the dielectric elastomer element 1A, the dielectric elastomer layer 11A (dielectric elastomer element 1A) is elongated, and the dielectric elastomer layer 11B (dielectric elastomer element 1B) to which no voltage is applied contracts along with the elongation of the dielectric elastomer layer 11A (dielectric elastomer element 1A). As a result, the supporting member 22 moves downward in the figure. On the other hand, when a voltage is applied only to the dielectric elastomer element 1B, the dielectric elastomer layer 11B (dielectric elastomer element 1B) is elongated, and the dielectric elastomer layer 11A (dielectric elastomer element 1A) to which no voltage is applied contracts along with the elongation of the dielectric elastomer layer 11B (dielectric elastomer element 1B). As a result, the supporting member 22 moves upward in the figure. When a voltage is applied by the controller 3 as described above, the dielectric elastomer transducer A11 transmits a force to the outside via the supporting member 22, and acts as an actuator.

The present variation also allows more stable use of the plurality of dielectric elastomer elements 1.

The dielectric elastomer transducer according to the present invention is not limited to the foregoing embodiments. Various design changes can be made to the specific configurations of the elements of the dielectric elastomer transducer according to the present invention.

Clause 1.

A dielectric elastomer transducer comprising:

a plurality of dielectric elastomer elements each including a dielectric elastomer layer and a pair of electrode layers flanking the dielectric elastomer layer,

wherein the plurality of dielectric elastomer elements include a first dielectric elastomer element and a second dielectric elastomer element that are adjacent to each other, and one of the electrode layers of the first dielectric elastomer element and one of the electrode layers of the second dielectric elastomer element are configured to have a same potential.

Clause 2.

The dielectric elastomer transducer according to clause 1, wherein each of the dielectric elastomer layers has an annular shape having an inner peripheral edge and an outer peripheral edge,

the inner peripheral edges or the outer peripheral edges of adjacent dielectric elastomer elements are fixed to each other, and the plurality of dielectric elastomer elements as a whole are elongated in an axial direction, with the respective dielectric elastomer elements having a shape of tubular frustum, and

the electrode layers of each dielectric elastomer element include an outer electrode layer in a radial direction, the outer electrode layer having zero or ground potential.

Clause 3.

The dielectric elastomer transducer according to clause 1, wherein each of the dielectric elastomer layers has an annular shape having an inner peripheral edge and an outer peripheral edge, and

the plurality of dielectric elastomer elements are stacked on each other with adjacent inner peripheral edges being fixed to each other and with adjacent outer peripheral edges being fixed to each other.

Clause 4.

A dielectric elastomer transducer, comprising at least one dielectric elastomer element made up of a dielectric elastomer layer and an electrode layer, wherein the dielectric elastomer element comprises:

a pair of dielectric elastomer layers stacked on each other;

an inner electrode layer flanked by the pair of dielectric elastomer layers; and

a pair of outer electrode layers flanking the pair of dielectric elastomer layers and having a same potential.

Clause 5.

The dielectric elastomer transducer according to clause 4, wherein each of the outer electrode layers has zero or ground potential.

Clause 6.

The dielectric elastomer transducer according to clause 4 or 5, wherein the dielectric elastomer element is wound in a roll shape, and

the pair of outer electrode layers have respective parts facing each other.

Clause 7.

The dielectric elastomer transducer according to clause 4 or 5, wherein the at least one dielectric elastomer element comprises a plurality of dielectric elastomer elements that are stacked on each other, and

the outer electrode layers of adjacent dielectric elastomer elements have a same potential.

1. A dielectric elastomer transducer comprising:
a plurality of dielectric elastomer elements each including a dielectric elastomer layer and a pair of electrode layers flanking the dielectric elastomer layer,
wherein the plurality of dielectric elastomer elements include a first dielectric elastomer element and a second dielectric elastomer element that are adjacent to each other, and one of the electrode layers of the first dielectric elastomer element and one of the electrode layers of the second dielectric elastomer element are configured to have a same potential.

2. The dielectric elastomer transducer according to claim 1, wherein each of the dielectric elastomer layers has an annular shape having an inner peripheral edge and an outer peripheral edge,
the inner peripheral edges or the outer peripheral edges of adjacent dielectric elastomer elements are fixed to each other, and the plurality of dielectric elastomer elements as a whole are elongated in an axial direction, with the respective dielectric elastomer elements having a shape of tubular frustum, and
the electrode layers of each dielectric elastomer element include an outer electrode layer in a radial direction, the outer electrode layer having zero or ground potential.

3. The dielectric elastomer transducer according to claim 1, wherein each of the dielectric elastomer layers has an annular shape having an inner peripheral edge and an outer peripheral edge, and
the plurality of dielectric elastomer elements are stacked on each other with adjacent inner peripheral edges being fixed to each other and with adjacent outer peripheral edges being fixed to each other.

4. A dielectric elastomer transducer, comprising at least one dielectric elastomer element made up of a dielectric elastomer layer and an electrode layer, wherein the dielectric elastomer element comprises:
a pair of dielectric elastomer layers stacked on each other;
an inner electrode layer flanked by the pair of dielectric elastomer layers; and
a pair of outer electrode layers flanking the pair of dielectric elastomer layers and having a same potential.

5. The dielectric elastomer transducer according to claim 4, wherein each of the outer electrode layers has zero or ground potential.

6. The dielectric elastomer transducer according to claim 4, wherein the dielectric elastomer element is wound in a roll shape, and
the pair of outer electrode layers have respective parts facing each other.

7. The dielectric elastomer transducer according to claim 4, wherein the at least one dielectric elastomer element comprises a plurality of dielectric elastomer elements that are stacked on each other, and
the outer electrode layers of adjacent dielectric elastomer elements have a same potential.

8. The dielectric elastomer transducer according to claim 5, wherein the dielectric elastomer element is wound in a roll shape, and
the pair of outer electrode layers have respective parts facing each other.

9. The dielectric elastomer transducer according to claim 5, wherein the at least one dielectric elastomer element comprises a plurality of dielectric elastomer elements that are stacked on each other, and
the outer electrode layers of adjacent dielectric elastomer elements have a same potential.
